(19) United States
(12) Patent Application Publication
(10) Pub. No.: US 2025/0372381 A1
(43) Pub. Date: Dec. 4, 2025

(54) ETCHING METHOD AND PLASMA PROCESSING APPARATUS

(71) Applicant: Tokyo Electron Limited, Tokyo (JP)

(72) Inventor: Takahiro YONEZAWA, Miyagi (JP)

(73) Assignee: Tokyo Electron Limited, Tokyo (JP)

(21) Appl. No.: 19/298,198

(22) Filed: Aug. 13, 2025

Related U.S. Application Data
(63) Continuation of application No. PCT/JP2024/004407, filed on Feb. 8, 2024.

(30) Foreign Application Priority Data
Feb. 21, 2023 (JP) 2023-025510

(51) Int. Cl. H01L 21/033; H01J 37/32; H01L 21/027

(52) U.S. Cl. CPC H01L 21/0337; H01J 37/32174; H01L 21/0276; H01L 21/0332; H01J 2237/3321; H01J 2237/3346

(57) ABSTRACT

The disclosed etching method includes: (a) providing a substrate that includes a first layer and a second layer having a pattern on the first layer, (b) forming a silicon containing layer on a surface of the second layer in preference to a surface of the first layer, (c) forming a metal containing layer on a surface of the silicon containing layer, and (d) etching the exposed first layer using the second layer, the silicon containing layer, and the metal containing layer as a mask.

### CROSS-REFERENCE TO RELATED APPLICATIONS

This application is a bypass continuation application of international application No. PCT/JP2024/004407 having an international filing date of Feb. 8, 2024 and designating the United States, the international application being based upon and claiming the benefit of priority from Japanese Patent Application No. 2023-025510, filed on Feb. 21, 2023, the entire contents of each are incorporated herein by reference.

### TECHNICAL FIELD

Exemplary embodiments of the present disclosure relate to an etching method and a plasma processing apparatus.

### BACKGROUND

PTL 1 discloses a method for producing a semiconductor device in which a substrate on which a pattern layer patterned by a lithography process is deposited is exposed to a plasma, thereby depositing a silicon containing layer on the pattern layer. The plasma is generated from a mixed gas containing SiCl₄ and one or more of argon, helium, nitrogen, and hydrogen.

### CITATION LIST

### Patent Documents

PTL 1: US2021/0183656

### SUMMARY

The present disclosure provides an etching method and a plasma processing apparatus capable of improving an etching selectivity ratio.

In an exemplary embodiment, an etching method is provided. The etching method includes: (a) providing a substrate that includes a first layer and a second layer having a pattern on the first layer, (b) forming a silicon containing layer on a surface of the second layer in preference to (i.e., in priority to) a surface of the first layer, (c) forming a metal containing layer on a surface of the silicon containing layer, and (d) etching the exposed first layer using the second layer, the silicon containing layer, and the metal containing layer as a mask.

According to one exemplary embodiment, a technique capable of improving an etching selectivity ratio is provided.

### BRIEF DESCRIPTION OF DRAWINGS

FIG. 1 is a diagram for explaining an example of a configuration of a plasma processing system.

FIG. 2 is a view for explaining an example of a configuration of a capacitively-coupled plasma processing apparatus.

FIG. 3 is a flowchart of an etching method according to one exemplary embodiment.

FIGS. 4A to 4D are schematic cross-sectional views illustrating the etching method in FIG. 3.

FIGS. 5A and 5B are schematic cross-sectional views illustrating a method for forming a resist layer according to one exemplary embodiment.

FIG. 6 is a flowchart of the method for forming the resist layer.

FIG. 7A is a schematic cross-sectional view illustrating surface processing on a silicon containing layer, and FIG. 7B is a schematic cross-sectional view illustrating trim etching of the silicon containing layer.

FIG. 8 is a flowchart of a method for forming the silicon containing layer.

FIG. 9A is a schematic cross-sectional view illustrating surface processing on a metal containing layer, and FIG. 9B is a schematic cross-sectional view illustrating trim etching of the metal containing layer.

FIG. 10 is a flowchart of a method for forming the metal containing layer.

FIG. 11A is a schematic cross-sectional view illustrating a method for generating a deposition layer according to a first modification, and FIG. 11B is a schematic cross-sectional view illustrating etching according to the first modification.

FIG. 12A is a schematic cross-sectional view illustrating etching according to a second modification, FIG. 12B is a schematic cross-sectional view illustrating a method for generating a deposition layer according to the second modification, and FIG. 12C is a schematic cross-sectional view illustrating etching according to the second modification.

FIGS. 13A and 13B are schematic cross-sectional views illustrating a method of generating a metal containing layer according to a third modification.

### DETAILED DESCRIPTION

Hereinafter, various exemplary embodiments will be described.

In an exemplary embodiment, an etching method is provided. The etching method includes: (a) providing a substrate that includes a first layer and a second layer having a pattern on the first layer, (b) forming a silicon containing layer on a surface of the second layer in preference to (i.e., in priority to) a surface of the first layer, (c) forming a metal containing layer on a surface of the silicon containing layer, and (d) etching the exposed first layer using the second layer, the silicon containing layer, and the metal containing layer as a mask.

In another exemplary embodiment, a plasma processing apparatus is provided. The plasma processing apparatus includes a chamber, a substrate support provided in the chamber and including a temperature control module, a gas supply configured to supply a processing gas into the chamber, a plasma generator configured to generate a plasma from the processing gas in the chamber, and a controller. The controller is configured to control the temperature control module, the gas supply, and the plasma generator such that, in a state in which a substrate including a first layer and a second layer having a pattern on the first layer is supported by the substrate support, a silicon containing layer is formed on a surface of the second layer in preference to a surface of the first layer, a metal containing layer is formed on a surface of the silicon containing layer, and the exposed first layer is etched using the second layer, the silicon containing layer, and the metal containing layer as a mask.

Hereinafter, various exemplary embodiments will be described in detail with reference to the drawings. Further, like reference numerals will be given to like or corresponding parts throughout the drawings.

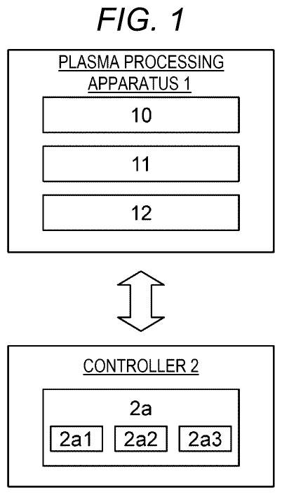

FIG. 1 is a diagram illustrating an example of a configuration of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting a substrate. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave-excited plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency within a range from 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions that cause the plasma processing apparatus 1 to execute various steps described in the present disclosure. The controller 2 may be configured to control elements of the plasma processing apparatus 1 to execute the various steps described herein below. In one embodiment, part or all of the controller 2 may be in the plasma processing apparatus 1. The controller 2 may include a processor 2al, a storage 2a2, and a communication interface 2a3. The controller 2 is implemented, for example, by a computer 2a. The processor 2al may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

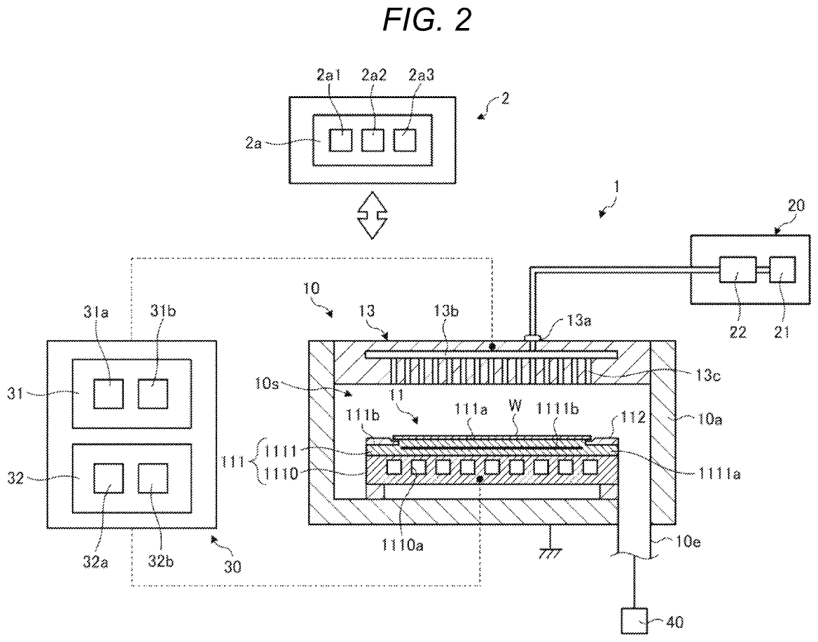

Hereinafter, an example of a configuration of a capacitively-coupled plasma processing apparatus as an example of the plasma processing apparatus 1 will be described. FIG. 2 is a diagram illustrating the example of the configuration of the capacitively-coupled plasma processing apparatus.

The capacitively-coupled plasma processing apparatus 1 includes the plasma processing chamber 10, the gas supply 20, a power source 30, and the exhaust system 40. The plasma processing apparatus 1 further includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from the housing of the plasma processing chamber 10. A process not using a plasma may be performed in the plasma processing space 10s. In other words, the steps performed in the plasma processing space 10s may include a step not using a plasma.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a is also called a substrate support surface that supports the substrate W, and the annular region 111b is also called a ring support surface that supports the ring assembly 112. The ring assembly 112 may be made of an inorganic material or an organic material, depending on the intended processing.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled to an RF power source 31 and/or a DC power source 32, which will be described later, may be disposed in the ceramic member 1111a. In this case, the at least one RF/DC electrode functions as the lower electrode. When a bias RF signal and/or DC signal, which will be described later, are supplied to the at least one RF/DC electrode, the RF/DC electrode is also called a bias electrode. The conductive member of the base 1110 and at least one RF/DC electrode may function as a plurality of lower electrodes. The electrostatic electrode 1111b may instead function as the lower electrode. Accordingly, the substrate support 11 includes at least one lower electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

The substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed in the base 1110, and one or more heaters are disposed in the ceramic member 1111a of the electrostatic chuck 1111. The substrate support 11 may further include a heat transfer gas supply configured to supply a heat transfer gas to a gap between a rear surface of the substrate W and the central region 111a. For example, the target temperature is −80° C. or higher and 50° C. or lower.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The shower head 13 further includes at least one upper electrode. The gas introduction unit may include, in addition to the shower head 13, one or a plurality of side gas injectors (SGI) that are attached to one or a plurality of openings formed in the sidewall 10a.

The gas supply 20 is a member that supplies the processing gas described above into the plasma processing chamber 10, and may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. Further, the gas supply 20 may include at least one flow rate modulation device that modulates or pulses a flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Plasma is thus generated from the at least one processing gas supplied into the plasma processing space 10s. Accordingly, the RF power source 31 may function as at least a part of the plasma generator 12. Supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to generate a source RF signal (source RF power) for plasma generation. The first RF generator 31a is coupled to the at least one lower electrode and/or the at least one upper electrode via the at least one impedance matching circuit. For example, when the first RF generator 31a is coupled to the upper electrode, the upper electrode may have a top plate such as a silicon top plate. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to the at least one lower electrode and/or at least one upper electrode.

The second RF generator 31b is coupled to the at least one lower electrode via the at least one impedance matching circuit and configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power source 30 may include the DC power source 32 coupled to the plasma processing chamber 10. The DC power source 32 includes a first DC generator 32a and a second DC generator 32b. In one embodiment, the first DC generator 32a is connected to at least one lower electrode to generate a first DC signal. The generated first DC signal is applied to the at least one lower electrode. In one embodiment, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. The sequence of the voltage pulses may include one or more positive voltage pulses and one or more negative voltage pulses in one cycle. The first DC generator 32a and the second DC generator 32b may be provided in addition to the RF power source 31, or the first DC generator 32a may be provided in place of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

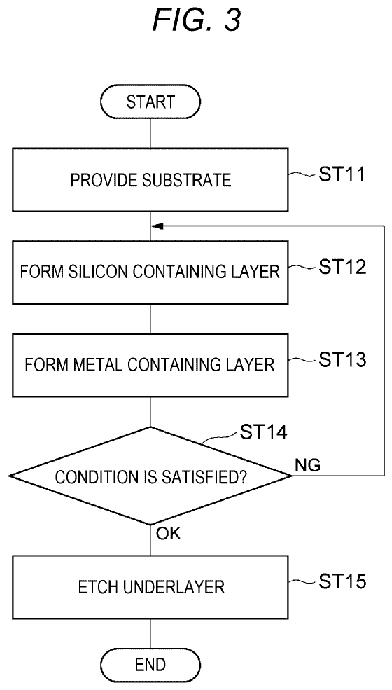

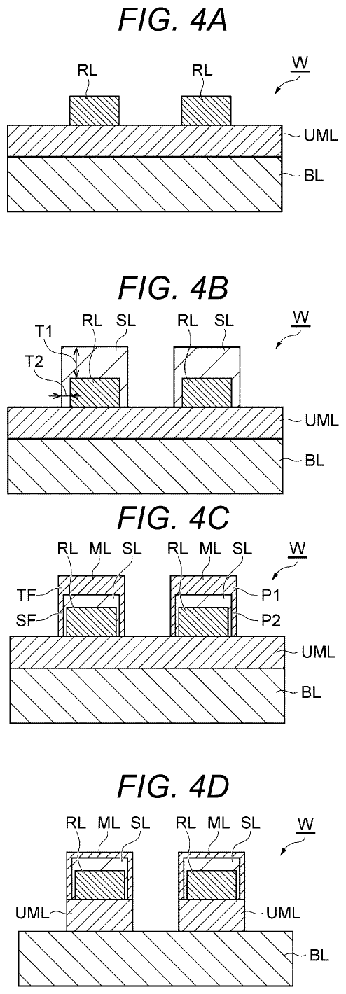

FIG. 3 is a flowchart of an etching method according to one exemplary embodiment. FIGS. 4A to 4D are schematic cross-sectional views illustrating the etching method in FIG. 3. An etching method MT1 illustrated in FIG. 3 (hereinafter referred to as “method MT1”) may be performed by the plasma processing apparatus 1 of the embodiment. The method MT1 may be applied to the substrate W illustrated in FIG. 4A.

FIG. 4A is a schematic cross-sectional view of an example substrate to which the etching method in FIG. 3 may be applied. As illustrated in FIG. 4A, in one embodiment, the substrate W may be a member used for producing a semiconductor device. The semiconductor device includes, for example, a semiconductor memory device, such as a DRAM or a 3D-NAND flash memory. The substrate W includes a base layer BL, an underlayer UML (first layer), and a resist layer RL (second layer) having a pattern on the underlayer UML. The base layer BL may be, for example, an organic film, a dielectric film, a metal film, a semiconductor film, or a stacked film thereof formed on a silicon wafer. For example, the base layer BL may contain silicon oxide, carbon-doped oxide, porous oxide, silicon nitride, silicon oxynitride, silicon, titanium nitride, titanium, tantalum nitride, and tantalum. The underlayer UML may be a film etched using the resist layer RL as a mask. The underlayer UML may function as a mask for the base layer BL. The underlayer UML is, for example, a spin-on-glass (SOG) film, a SiON film, a Si containing antireflection film (SiARC), or an organic film.

The resist layer RL is a layer that may function as a part of an etching mask for the underlayer UML, and may be a metal containing resist film containing a metal. The metal may contain, for example, at least one metal selected from the group consisting of Sn, Hf, and Ti. For example, the resist layer RL contains Sn and may contain tin oxide (SnO). The resist layer RL may contain an organic substance.

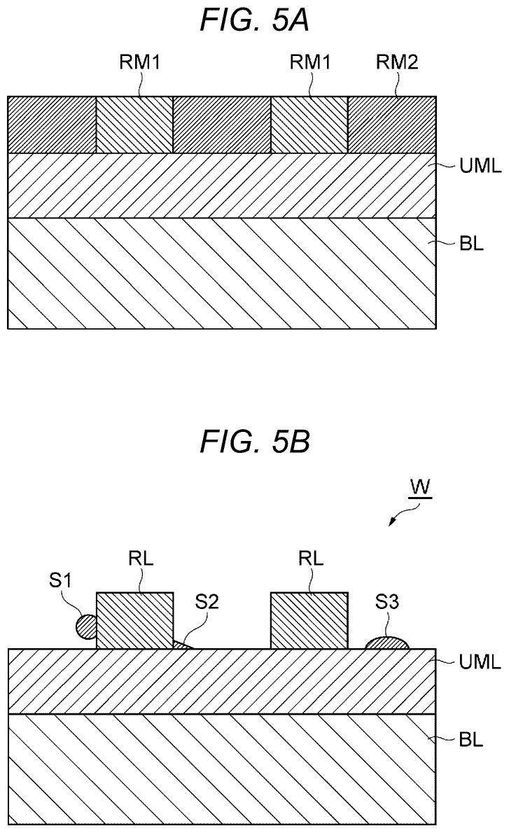

Hereinafter, an example of a method for forming the resist layer RL (resist forming step) will be described with reference to FIG. 5A. First, a photoresist film containing a metal is formed on the underlayer UML subjected to adhesion processing. The photoresist film may be formed by a dry process, a wet process, or both a dry process and a wet process. After the photoresist film is formed, the photoresist film is subjected to, for example, a heating treatment such as pre-baking. After the heating treatment, the photoresist film is irradiated with extreme ultraviolet light (EUV) by using an exposure apparatus and an exposure mask (reticle). Accordingly, as illustrated in FIG. 5A, an exposed first region RM1 and an unexposed second region RM2 are formed. The first region RM1 is an EUV exposure region corresponding to an opening provided in the exposure mask. The second region RM2 is an EUV unexposed region corresponding to a pattern provided in the exposure mask. The EUV has, for example, a wavelength in a range of 10 nm to 20 nm. The EUV may have a wavelength in a range of 11 nm to 14 nm, and has, for example, a wavelength of 13.5 nm.

Subsequently, the second region RM2 is selectively removed in development processing. Accordingly, the resist layer RL which is derived from the first region RM1 and has a pattern is formed on the underlayer UML. In the development processing, a part of the first region RM1 may also be removed. In this case, the second region RM2 is removed at a first selectivity ratio with respect to the first region RM1. The “selectivity ratio” in the present development processing is also referred to as development contrast, and corresponds to a ratio of a development speed of the second region RM2 to a development speed of the first region RM1. The development processing may be a dry process, a wet process, or both a dry process and a wet process.

In one embodiment, the development processing uses a first processing gas, such as a halogen containing gas. The halogen containing gas may be a gas containing a halogen containing inorganic acid, and may be a gas of an inorganic acid containing Br, Cl, or the like. The gas containing a halogen containing inorganic acid is, for example, at least one selected from the group consisting of an HBr gas, a BCl₃ gas, HCl, and HF. In one embodiment, the first processing gas may be a gas containing an organic acid. The gas containing an organic acid may be, for example, a gas containing at least one selected from the group consisting of carboxylic acid, a β-dicarbonyl compound, and an alcohol. The carboxylic acid may be, for example, formic acid (HCOOH), acetic acid (CH₃COOH), trichloroacetic acid (CCl₃COOH), monofluoroacetic acid (CFH₂COOH), difluoroacetic acid (CF₂HCOOH), trifluoroacetic acid (CF₃COOH), chloro-difluoroacetic acid (CClF₂COOH), sulfur containing acetic acid, thioacetic acid (CH₃COSH), thioglycolic acid (HSCH₂COOH), trifluoroacetic anhydride (CF₃CO)₂O), or acetic anhydride (CH₃CO)₂O). The β-dicarbonyl compound may be, for example, acetyl acetone (CH₃C(O)CH₂C(O)CH₃), trichloroacetylacetone (CCl₃C(O)CH₂C(O)CH₃), hexachloroacetylacetone (CCl₃C(O)CH₂C(O)CCl₃), trifluoroacetylacetone (CF₃C(O)CH₂C(O)CH₃), or hexafluoroacetyl acetone (HFAc, CF₃C(O)CH₂C(O)CF₃). The alcohol may be, for example, nonafluoro-tert-butyl alcohol ((CF₃)₃COH). In one embodiment, the first processing gas contains trifluoroacetic acid. In one embodiment, the first processing gas contains halogenated organic acid vapor. The first processing gas contains, for example, at least one selected from the group consisting of trifluoroacetic anhydride, acetic anhydride, trichloroacetic acid, CFH₂COOH, CF₂HCOOH, chloro-difluoroacetic acid, sulfur containing acetic acid, thioacetic acid, and thioglycolic acid. In one embodiment, the first processing gas is a mixture of carboxylic acid and hydrogen halide or a mixture of acetic acid and formic acid.

FIG. 5B is a schematic cross-sectional view illustrating an example after the development processing. As illustrated in FIG. 5B, after the development processing, scums (residues) S1 to S3 that cannot be removed are generated on the substrate W. The scum S1, which is a residue, is a resist or a by-product thereof that scatters from the second region RM2 and adheres to the resist layer RL. The scums S2 and S3 are remaining portions of the second region RM2 without being removed. The scums S2 and S3 may be a convex on a surface of the resist layer RL and/or a surface of the underlayer UML. The scums S1 to S3 may have various shapes and sizes. At least one of the scums S1 to S3 may be generated after the development processing.

When the scums S1 to S3 are generated after the development processing as illustrated in FIG. 5B, the scums may be removed in the following descum step. For example, all of the scums S1 to S3 on the substrate W may be removed by a plasma generated from a second processing gas. For example, first, the second processing gas is supplied from the gas supply 20 into the plasma processing space 10s. Next, the source RF signal is supplied to the upper electrode or the lower electrode. Accordingly, a high-frequency electric field is generated in the plasma processing space 10s, and the plasma is generated from the second processing gas. At this time, the bias signal may be supplied to the lower electrode of the substrate support 11. Then, the scums S1 to S3 are removed by the plasma generated from the second processing gas. The descum step may be performed when at least one of the scums S1 to S3 is generated.

In the descum step, the second processing gas may contain at least one selected from the group consisting of a helium containing gas, a hydrogen containing gas, a bromine containing gas, and a chlorine containing gas. For example, the second processing gas may contain at least one selected from the group consisting of a helium gas, a hydrogen gas, a hydrogen bromide gas, and a boron trichloride gas. The second processing gas may further contain a noble gas such as an Ar gas and an inert gas such as an N₂ gas.

### (Step ST11: Provision of Substrate)

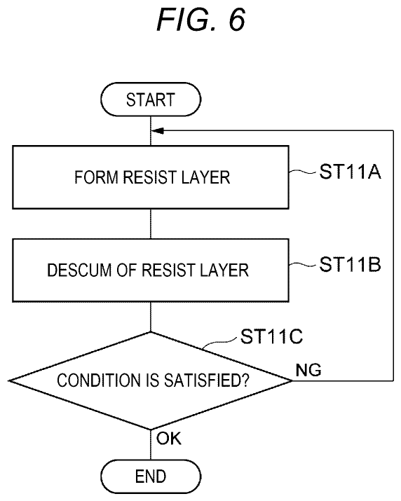

As illustrated in FIG. 3, first, the substrate W that includes the underlayer UML and the resist layer RL having a pattern on the underlayer UML is provided into the plasma processing chamber 10 (step ST11). In step ST11, the substrate W is provided on the substrate support 11. Accordingly, the substrate W is supported by the substrate support 11. Next, an example of a formation method when the resist layer RL is formed in step ST11 will be described with reference to FIG. 6. FIG. 6 is a flowchart of the method for forming the resist layer. As illustrated in FIG. 6, first, the resist layer RL having a pattern is formed on the underlayer UML (step ST11A). In step ST11A, for example, the resist layer RL having a pattern is formed by photolithography or the like (see FIG. 5A). Subsequently, the scums S1 to S3 (see FIG. 5B) that adhere to the resist layer RL and the underlayer UML are removed (step ST11B, the descum step). If a predetermined condition is satisfied after step ST11B (YES in step ST11C), step ST12 to be described later is performed. On the other hand, if the predetermined condition is not satisfied after step ST11B (NO in step ST11C), steps ST11A and ST11B are performed again. The predetermined condition described above includes at least one of a pattern shape of the resist layer RL, a thickness of the resist layer RL, and the number of scums. Either step ST11A or step ST11B may not be performed in the second and subsequent steps.

### (Step ST12: Formation of Silicon Containing Layer)

Next, as illustrated in FIG. 4B, a silicon containing layer SL is formed on the surface of the resist layer RL with priority over the surface of the underlayer UML (step ST12). In step ST12, the silicon containing layer SL is formed by using a plasma generated from the third processing gas supplied into the plasma processing chamber 10. For example, first, the third processing gas is supplied from the gas supply 20 into the plasma processing space 10s. Next, the source RF signal is supplied to the upper electrode or the lower electrode. Accordingly, a high-frequency electric field is generated in the plasma processing space 10s, and the plasma is generated from the third processing gas. Then, radicals containing silicon contained in the plasma are deposited on the surface of the resist layer RL. In step ST12, the temperature (target temperature) of the substrate W may be adjusted by the temperature control module of the substrate support 11.

Forming the silicon containing layer SL preferentially on the surface of the resist layer RL over the surface of the underlayer UML may correspond to selectively forming the silicon containing layer SL on the surface of the resist layer RL. In step ST12, the silicon containing layer SL may be formed only on the surface of the resist layer RL, or the silicon containing layer SL may be formed on both the surface of the resist layer RL and the surface of the underlayer UML. In the latter case, a thickness of a portion provided on the surface of the resist layer RL may be significantly larger than a thickness of a portion provided on the surface of the underlayer UML.

The silicon containing layer SL is a layer that may function as a part of the etching mask for the underlayer UML. In one embodiment, the silicon containing layer SL is a deposit of an amorphous material containing silicon. The silicon containing layer SL has a first portion P1 located on a top surface TF of the resist layer RL and a second portion P2 located on a side surface SF of the resist layer RL. In one embodiment, a thickness T1 of the first portion P1 is larger than a thickness T2 of the second portion P2. For example, the thickness T1 may be 1 times or more and 10 times or less than the thickness T2. The thickness T1 is, for example, 5 nm or more and 20 nm or less. For example, the silicon containing layer SL may have the first portion P1 without the second portion P2. In other words, the silicon containing layer SL may have only the first portion P1.

The third processing gas contains a source gas including a silicon containing gas, and a dilution gas, such as argon, helium, or nitrogen. In addition thereto, the third processing gas may further contain at least one additive gas of a halogen containing gas such as Cl₂ and a hydrogen containing gas such as H₂, CH₄, or CH_{X}F_{4-X}. The silicon containing gas may be silicon tetrafluoride (SiF₄), silicon tetrachloride (SiCl₄), Si₂Cl₆, SiH₄, Si₂H₆, or the like.

In one embodiment, the frequency of the source RF signal in step ST12 may be in a high frequency band (for example, 10 MHz or more and 1 GHz or less), or may be in a low frequency band (for example, 100 Hz or more and 100 kHz or less). The RF power is, for example, 100 W or more and 1.5 kW or less. A flow rate of the source gas contained in the third processing gas is, for example, 2 sccm or more and 250 sccm. Pressure in the plasma processing chamber 10 is, for example, 5 m Torr or more and 250 m Torr or less, and the temperature of the substrate W is 0° C. or higher and 120° C. or lower.

For example, in step ST12, the surface of the resist layer RL is first activated, and subsequently, silane is bonded to the surface. Then, silicon atoms are bonded together to form the silicon containing layer SL preferentially on the surface of the resist layer RL over the surface of the underlayer UML. For a specific example of the method, see, for example, the information disclosed in U.S. patent application Ser. No. 17/658,538.

In step ST12, the silicon containing layer SL may be formed without generating the plasma in the plasma processing chamber 10. In this case, the silicon containing layer SL is formed by supplying the silicon containing gas into the plasma processing chamber 10. In this case, the silicon containing layer SL is formed through, for example, a chemical vapor deposition method (CVD method). When the silicon containing layer SL is formed without generating the plasma, at least one of the dilution gas and the additive gas may be supplied to the plasma processing chamber 10, in addition to the silicon containing gas.

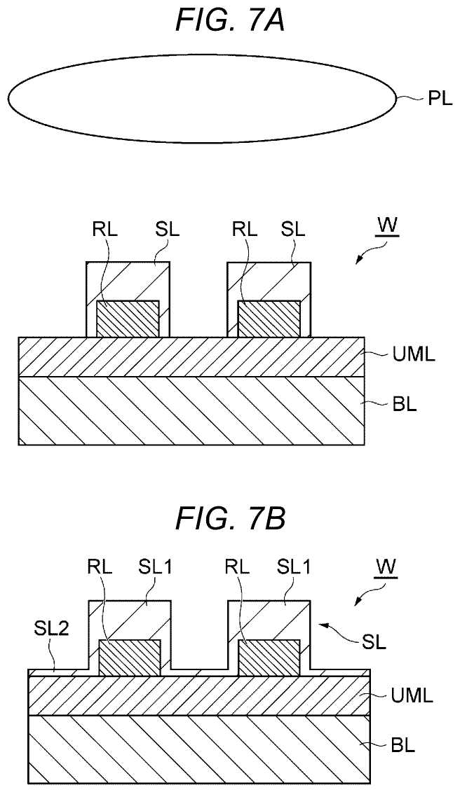

As illustrated in FIG. 7A, after the silicon containing layer SL is formed in step ST12, the silicon containing layer SL may be exposed to a plasma PL generated from a hydrogen containing gas before the next step ST13 is performed. Accordingly, a surface treatment is performed on the silicon containing layer SL. Specifically, Si—H bonds are generated on a surface of the silicon containing layer SL. In this case, in the next step ST13, the metal is easily deposited on the surface of the silicon containing layer SL. Examples of the hydrogen containing gas include hydrocarbons such as CH₄ and CO₂H₆, hydrofluorocarbons such as CH₂F₂ and CHF₃, nitrogen containing gases such as NH₃, halogen containing gases such as HF, HCl, HBr, and HI, and hydrogen.

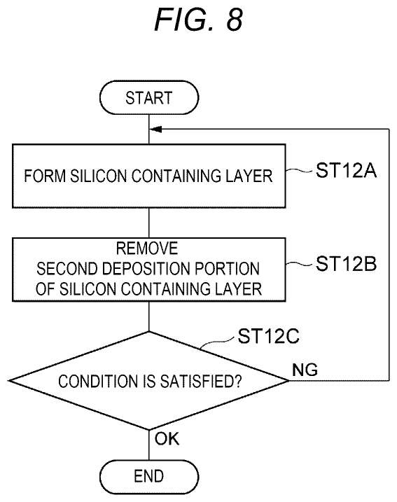

As illustrated in FIG. 7B, the silicon containing layer SL may include a first deposition portion SL1 deposited on the surface of the resist layer RL and a second deposition portion SL2 deposited on the surface of the underlayer UML. In this case, as illustrated in FIG. 8, after the silicon containing layer SL is formed in step ST12, a part of the silicon containing layer SL may be removed before the next step ST13 is performed. For example, trim etching is performed to remove the second deposition portion SL2 deposited on the surface of the underlayer UML. An example of a method for forming the silicon containing layer SL when the trim etching is performed in step ST12 will be described with reference to FIG. 8. FIG. 8 is a flowchart of a method for forming the silicon containing layer. As illustrated in FIG. 8, first, the silicon containing layer SL is formed on the surface of the resist layer RL (step ST12A). Subsequently, the second deposition portion SL2 of the silicon containing layer SL is removed (step ST12B). In step ST12B, a part of the first deposition portion SL1 may be removed. The trim etching is, for example, plasma etching using fluorocarbon, fluorine, chlorine, or hydrogen bromide as etchants. If a predetermined condition is satisfied after step ST12B (YES in step ST12C), step ST13 to be described later is performed. On the other hand, if the predetermined condition is not satisfied after step ST12B (NO in step ST12C), steps ST12A and ST12B are performed again. The predetermined condition is at least one of a thickness and a shape of the first deposition portion SL1 of the silicon containing layer SL. Either step ST12A or step ST12B may not be performed in the second and subsequent steps. By performing the trim etching on the silicon containing layer SL as described above, a part of the underlayer UML can be reliably exposed at the end of step ST12.

### (Step ST13: Formation of Metal Containing Layer)

Next, as illustrated in FIG. 4C, a metal containing layer ML is formed on the surface of the silicon containing layer SL (step ST13). In step ST13, the metal containing layer ML is formed from a fourth processing gas supplied into the plasma processing chamber 10.

The metal containing layer ML is a layer that may function as the etching mask for the underlayer UML, and contains at least a metal. The metal may contain at least one of tungsten and molybdenum. For example, the metal containing layer ML contains at least one of W, WSi_{X}, Mo, and MoSi_{X}F_{Y} (each of X and Y is a positive number). The metal containing layer ML may contain at least one of F and Cl as a trace element. In one embodiment, the trace element in the metal containing layer ML may be an element having a content ratio (mass ratio) less than a content ratio (mass ratio) of the metal in the metal containing layer ML. A thickness of the metal containing layer ML may be uniform or non-uniform. The metal containing layer ML may be a layer in which a part of the silicon containing layer SL is metal silicided, or may be a new layer formed on the silicon containing layer SL. In the former case, a boundary between the metal containing layer ML and the silicon containing layer SL may or may not be clear. In the latter case, the metal containing layer ML is a layered deposit containing a metal.

The metal containing layer ML may be provided only on the surface of the silicon containing layer SL, or may be provided on both the surface of the silicon containing layer SL and the surface of the underlayer UML. In the latter case, the metal containing layer ML may be formed preferentially on the surface of the silicon containing layer SL over the surface of the underlayer UML. In this case, the thickness of the portion provided on the surface of the silicon containing layer SL may be significantly larger than the thickness of the portion provided on the surface of the underlayer UML. Forming the metal containing layer ML preferentially on the surface of the silicon containing layer SL over the surface of the underlayer UML may correspond to selectively forming the metal containing layer ML on the surface of the silicon containing layer SL.

The fourth processing gas contains a source gas containing a metal and a dilution gas such as argon, helium, or nitrogen. The source gas may contain fluorine. The source gas may include, for example, at least one of a tungsten hexafluoride (WF₆) gas, a tungsten hexachloride (WCl₆) gas, and a molybdenum pentafluoride (MoF₅) gas. In this case, a metal compound contained in the source gas may contain at least one of tungsten hexafluoride (WF₆), tungsten hexachloride (WCl₆), and molybdenum pentafluoride (MoF₅). When the plasma is used in step ST13, the fourth processing gas may contain H₂ or the like.

In an example of step ST13, the metal containing layer ML is formed by a chemical vapor deposition method (CVD method) without generating the plasma. First, the fourth processing gas is supplied from the gas supply 20 into the plasma processing space 10s. At this time, the substrate W is heated to 60° C. or higher by the temperature control module of the substrate support 11. Accordingly, silicon located on the surface of the silicon containing layer SL undergoes a thermochemical reaction with the metal contained in the fourth processing gas. Accordingly, the silicon and the metal are bonded to form silicide. Then, the metal containing layer ML derived from the silicide is formed. In the example described above, the source RF signal in step ST13 may not be input. In this case, the RF power may be 0. Similarly, the DC voltage may be 0 V. A flow rate of the source gas contained in the fourth processing gas is, for example, 2 sccm or more and 250 sccm or less. Pressure in the plasma processing chamber 10 is, for example, 10 m Torr or more and 250 mTorr or less, and the temperature of the substrate W is 60° C. or higher and 130° C. or lower.

In another example of step ST13, the metal containing layer ML is formed by an atomic layer deposition method (ALD method). In this case, the metal containing layer ML may be formed in a conformal manner or a sub-conformal manner. For example, the ALD method is performed by repeating a cycle including the following first to fourth steps. In the first step, a precursor gas is supplied to the substrate W. In the second step, the plasma processing chamber 10 in which the substrate W is housed is purged. In the third step, a reactive gas is supplied to the substrate W. In the third step, a plasma may be generated from the reactive gas. In the fourth step, the plasma processing chamber 10 is purged. For example, the cycle described above is, for example, 60 cycles or more and 100 cycles or less. The precursor gas may be a source gas containing a metal, or may be the same as the fourth processing gas. The reactive gas may contain at least an oxygen containing gas (such as oxygen radicals). The reactive gas described above may contain a dilution gas. In another example described above, the source RF signal in step ST13 may not be input. In this case, the RF power may be 0. Similarly, the DC voltage may be 0 V. A flow rate of the precursor gas and a flow rate of the reactive gas are, for example, 2 sccm or more and 250 sccm or less. Pressure in the plasma processing chamber 10 is, for example, 100 m Torr or more and 400 mTorr or less, and the temperature of the substrate W is 60° C. or higher and 130° C. or lower.

In still another example of step ST13, the metal containing layer ML is formed by a plasma CVD method. First, the fourth processing gas is supplied from the gas supply 20 into the plasma processing space 10s. Next, the source RF signal is supplied to the upper electrode or the lower electrode. Accordingly, a high-frequency electric field is generated in the plasma processing space 10s, and the plasma is generated from the fourth processing gas. Then, radicals containing the metal contained in the plasma are deposited on the surface of the silicon containing layer SL. A flow rate of the source gas contained in the fourth processing gas is, for example, 2 sccm or more and 250 sccm or less.

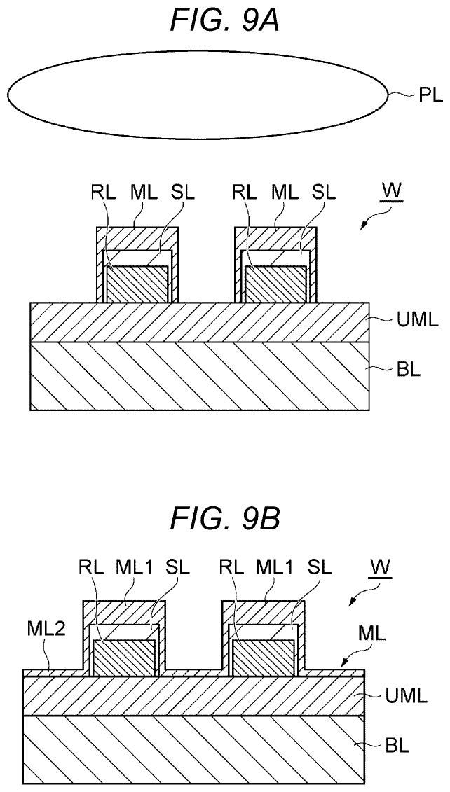

As illustrated in FIG. 9A, after the metal containing layer ML is formed in step ST13, the metal containing layer ML may be exposed to the plasma PL generated from the hydrogen containing gas before step ST15 to be described later is performed. Accordingly, a surface treatment is performed on the metal containing layer ML. For example, the surface of the metal containing layer ML is subjected to a reduction treatment. Accordingly, halogen on the surface of the metal containing layer ML may be desorbed.

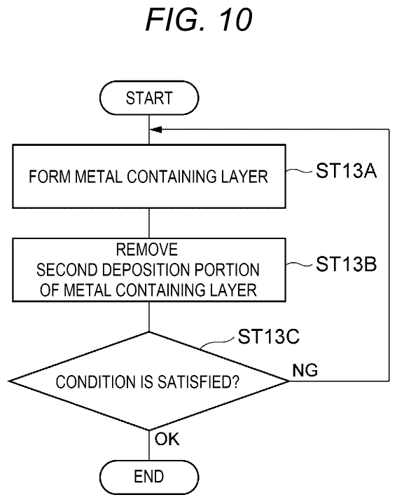

As illustrated in FIG. 9B, the metal containing layer ML may include a first deposition portion ML1 deposited on the surface of the silicon containing layer SL and a second deposition portion ML2 deposited on the surface of the underlayer UML. In particular, in another example and still another example described above, the second deposition portion ML2 tends to be formed. In this case, as illustrated in FIG. 10, after the metal containing layer ML is formed in step ST13, a part of the metal containing layer ML may be removed before step ST15 to be described later is performed. For example, trim etching for removing the second deposition portion ML2 deposited on the surface of the underlayer UML is performed. Here, an example of a method for forming the metal containing layer ML when the trim etching is performed in step ST13 will be described with reference to FIG. 10. FIG. 10 is a flowchart of a method for forming the metal containing layer. As illustrated in FIG. 10, first, the metal containing layer ML is formed on the surface of the silicon containing layer SL (step ST13A). Subsequently, the second deposition portion ML2 of the metal containing layer ML is removed (step ST13B). A part of the first deposition portion ML1 may be removed. The trim etching is, for example, plasma etching using fluorocarbon, fluorine, chlorine, or hydrogen bromide as etchants. If a predetermined condition is satisfied after step ST13B (YES in step ST13C), step ST15 to be described later is performed. On the other hand, if the predetermined condition is not satisfied after step ST13B (NO in step ST13C), steps ST13A and ST13B are performed again. The predetermined condition is at least one of a thickness and a shape of the first deposition portion ML1 of the metal containing layer ML. Either step ST13A or step ST13B may not be performed in the second and subsequent steps. By performing the trim etching on the metal containing layer ML as described above, a part of the underlayer UML can be reliably exposed at the end of step ST13.

If a predetermined condition is satisfied after step ST13 (YES in step ST14), step ST15 to be described later is performed. On the other hand, if the predetermined condition is not satisfied in step ST14 (NO in step ST14), steps ST12 and ST13 are performed again. Accordingly, in step ST15 to be described later, the underlayer UML can be satisfactorily etched. The predetermined condition described above is at least one of a thickness and a shape of a structure including the resist layer RL, the silicon containing layer SL, and the metal containing layer ML.

### (Step ST15: Etching of Underlayer UML)

Next, as illustrated in FIG. 4D, the underlayer UML is etched using the resist layer RL, the silicon containing layer SL, and the metal containing layer ML as a mask (step ST15). In step ST15, a plasma is generated from a fifth processing gas supplied into the plasma processing chamber 10. Subsequently, a portion of the underlayer UML exposed from the resist layer RL, the silicon containing layer SL, and the metal containing layer ML is exposed to the plasma. Accordingly, the underlayer UML having a pattern is formed, and a part of the base layer BL is exposed. After step ST15, the portion of the base layer BL exposed from the underlayer UML may be etched in the plasma processing chamber 10, or may be etched in an etching apparatus different from the plasma processing apparatus 1. In step ST15, not only the underlayer UML but also the metal containing layer ML may be etched. In step ST15, the temperature (target temperature) of the substrate W may be adjusted by the temperature control module of the substrate support 11.

When the underlayer UML is a spin-on-glass (SOG) film, a SiON film, or a Si containing antireflection (SiARC) film, the fifth processing gas contains, for example, a fluorine-based etchant or a chlorine-based etchant. When the underlayer UML is an organic film, the fifth processing gas contains, for example, a fluorocarbon gas, a hydrogen bromide gas, an oxygen gas, a carbon dioxide gas, and a carbon monoxide gas. The etching (plasma etching) using the plasma generated from the fifth processing gas may be anisotropic etching.

In step ST12, the controller 2 controls at least one of the temperature control module of the substrate support 11, the gas supply 20, and the plasma generator 12 to form the silicon containing layer SL preferentially on the surface of the resist layer RL over the surface of the underlayer UML. In step ST13, the controller 2 controls the temperature control module of the substrate support 11 and the gas supply 20 to form the metal containing layer ML on the surface of the silicon containing layer SL. In step ST15, the controller 2 controls at least one of the temperature control module of the substrate support 11, the gas supply 20, and the plasma generator 12 to etch the exposed underlayer UML using the resist layer RL, the silicon containing layer SL, and the metal containing layer ML as a mask.

According to the method MT1, the etching selectivity ratio can be improved. More specifically, the etching selectivity ratio of the underlayer UML to the mask including the resist layer RL, the silicon containing layer SL, and the metal containing layer ML can be improved. For example, when the outermost surface of the mask is the metal containing layer ML, the etching resistance of the mask to the fifth processing gas may be improved with compared to when the outermost surface of the mask is the silicon containing layer SL.

In one embodiment, the metal containing layer ML may be formed by the chemical vapor deposition method without generating the plasma. In this case, the metal containing layer ML can be selectively formed on the silicon containing layer SL. Therefore, the step of removing the unnecessary metal containing layer ML can be omitted. In one embodiment, the temperature of the substrate is controlled to 60° C. or higher in step ST13, thereby satisfactorily generating the thermochemical reaction.

In one embodiment, the metal containing layer ML may be formed by the atomic layer deposition method without generating the plasma. In this case, the thickness of the metal containing layer ML can be controlled in atomic layer units. Therefore, the pattern of the underlayer UML can be accurately formed. In one embodiment, the temperature of the sub strate is controlled to 60° C. or higher in step ST13, thereby easily forming the metal containing layer ML.

In one embodiment, before step ST11, when the resist layer RL is formed on the underlayer UML and at least one of the scums S1 to S3 is present on the substrate W after the resist layer RL is formed, the scums S1 to S3 on the substrate W may be removed. In this case, it is possible to prevent the occurrence of a process failure caused by scums.

In one embodiment, the silicon containing layer SL may be exposed to the plasma PL generated from the hydrogen containing gas after step ST12 and before step ST13. In this case, the metal containing layer ML is easily formed on the surface of the silicon containing layer SL.

In one embodiment, after step ST12 and before step ST13, a part of the silicon containing layer SL may be removed. In this case, before step ST13, a portion of the underlayer UML that is not covered with the resist layer RL can be reliably exposed.

In one embodiment, after step ST13 and before step ST15, the metal containing layer ML may be exposed to the plasma PL generated from the hydrogen containing gas. In this case, the etching resistance of the metal containing layer ML can be improved.

In one embodiment, after step ST13 and before step ST15, a part of the metal containing layer ML may be removed. In this case, before step S14, a portion of the underlayer UML that is not covered with the resist layer RL and the silicon containing layer SL can be reliably exposed.

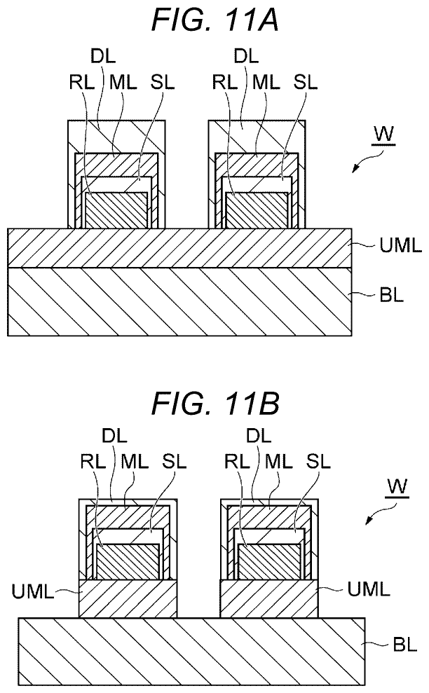

Hereinafter, etching methods according to modifications of the exemplary embodiment will be described with reference to FIGS. 11 to 13. In the description of each modification, descriptions overlapping with the exemplary embodiment will be omitted, and portions different from the exemplary embodiment will be described. In other words, the descriptions of the exemplary embodiment may be appropriately used for each modification to the extent technically possible.

### FIRST MODIFICATION

A first modification differs from the exemplary embodiment in that further film formation is performed between step ST13 and step ST15. In the first modification, as illustrated in FIG. 11A, a deposition layer DL is formed on the surface of the metal containing layer ML after step ST13 and before step ST15. The deposition layer DL is, for example, a deposit of an amorphous material containing silicon, similarly to the silicon containing layer SL. For example, as in step ST12, the deposition layer DL is formed using the plasma generated from the third processing gas supplied into the plasma processing chamber 10. In this case, the silicon containing layer SL may be formed preferentially on the surface of the metal containing layer ML over the surface of the underlayer UML. The deposition layer DL may be formed only on the surface of the metal containing layer ML, or the deposition layer DL may be formed on both the surface of the metal containing layer ML and the surface of the underlayer UML. In the latter case, a part of the deposition layer DL may be removed until the underlayer UML is exposed. In other words, in the latter case, trim etching may be performed.

After the deposition layer DL is formed, step ST15 is performed. Accordingly, as illustrated in FIG. 11B, the underlayer UML is etched using the resist layer RL, the silicon containing layer SL, the metal containing layer ML, and the deposition layer DL as a mask. At this time, the deposition layer DL is also etched. The entire deposition layer DL may be etched.

Also in the first modification described above, the same effects as in the exemplary embodiment described above are achieved. In addition, since the function of the mask can be reliably exhibited in step ST15, an etching defect is unlikely to occur.

In the first modification, after the deposition layer DL is formed, a metal containing layer may be formed on the surface of the deposition layer DL before step ST15. For example, the metal containing layer is formed in the same manner as in step ST13. After the metal containing layer is formed, a deposition layer may be further formed before step ST15. For example, a cycle of step ST12 and step ST13 may be performed repeatedly before step ST15.

The cycle is, for example, 60 cycles or more and 100 cycles or less.

### SECOND MODIFICATION

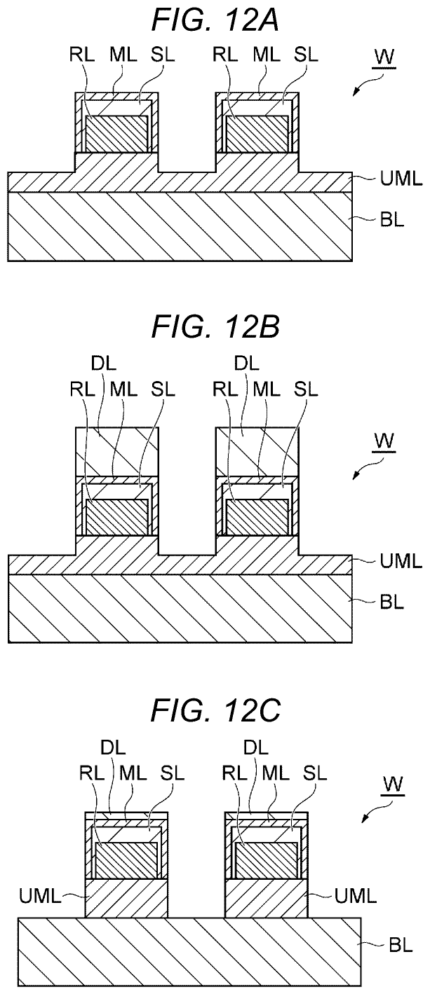

The second modification differs from the exemplary embodiment in that a process other than etching of the underlayer UML is performed in step ST15. In the second modification, as illustrated in FIG. 12A, substantially the entire metal containing layer ML may be removed before the etching of the underlayer UML is ended in step ST15. In consideration of such a case, as illustrated in FIG. 12B, step ST15 is interrupted, and the deposition layer DL is formed on the surface of the metal containing layer ML. For example, the deposition layer DL is formed in the same manner as in the first modification. After the deposition layer DL is formed, step ST15 is restarted. Accordingly, as illustrated in FIG. 12C, the underlayer UML may be etched.

Also in the second modification described above, the same effects as in the exemplary embodiment described above are achieved. In addition, it is possible to prevent occurrence of a pattern formation defect or the like in step ST15.

The second modification may be combined with the first modification. In this case, after step ST15 is interrupted, the deposition layer DL and the metal containing layer ML may be formed. In other words, after step ST15 is interrupted, a cycle of step ST12 and step ST13 may be performed. At this time, the cycle may be performed a plurality of times.

### THIRD MODIFICATION

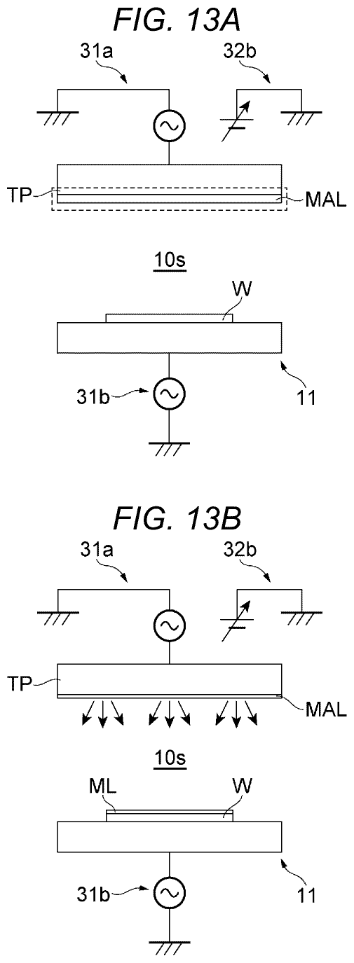

The third modification differs from the exemplary embodiment in that a sputtering method is used in step ST13. In the third modification, after step ST12, a surface of a Si top plate TP included in an upper electrode is cleaned (see FIG. 13A). For example, the surface of the Si top plate TP is cleaned by performing ion sputtering. In another example, the surface of the Si top plate TP is cleaned by introducing a reducing gas such as hydrogen fluoride into the plasma processing space 10s. Accordingly, an oxide film (not illustrated) that may be provided on the surface of the Si top plate TP is removed, and the surface is cleaned. In the cleaning, a signal may be input to the first RF generator 31a, or a voltage may be applied to the second DC generator 32b. The cleaning of the surface of the Si top plate TP is performed instead of step ST12 and may also serve as the formation of the silicon containing layer in step ST12.

Subsequently, as illustrated in FIG. 13A, a metal layer MAL is formed on the Si top plate TP. For example, a source gas containing a metal is introduced into the plasma processing space 10s. Accordingly, the metal layer MAL, which is an atomic layer of the metal, is formed on the surface of the Si top plate TP through a thermochemical reaction. At this time, the signal may not be input to the first RF generator 31a, or the voltage may not be applied to the second DC generator 32b.

Next, as illustrated in FIG. 13B, the metal containing layer ML is formed on the substrate W by ion sputtering the metal layer MAL. For example, a signal is input to the first RF generator 31a or a voltage is applied to the second DC generator 32b, causing ions to collide with the metal layer MAL in the plasma processing space 10s. Accordingly, the metal containing layer ML is formed on the surface of the silicon containing layer SL included in the substrate W. In the third modification, a cycle of a formation step of the metal layer MAL and a formation step of the metal containing layer ML may be performed repeatedly. Accordingly, the thickness of the metal containing layer ML can be adjusted. The cycle is, for example, 60 cycles or more and 100 cycles or less. When the metal containing layer ML is also formed on the surface of the underlayer UML, the trim etching may be performed. After the above steps, step S14 is performed.

Also in the third modification described above, the same effects as in the exemplary embodiment described above are achieved. Since a ratio of the metal contained in the metal containing layer ML can be increased, the etching resistance of the metal containing layer ML can be improved. In addition, the thickness of the metal containing layer ML can be accurately adjusted.

While various exemplary embodiments have been described above, various additions, omissions, substitutions and changes may be made without being limited to the exemplary embodiments described above. In addition, other embodiments may be formed by combining elements in different embodiments. For example, the method MT may be performed using a plasma processing apparatus different from the plasma processing apparatus 1.

Hereinafter, various exemplary embodiments included in the present disclosure will be described in [E1] to [E14].

### [E1]

An etching method including:
(a) providing a substrate that includes a first layer and a second layer having a pattern on the first layer,
(b) forming a silicon containing layer on a surface of the second layer in preference to a surface of the first layer,
(c) forming a metal containing layer on a surface of the silicon containing layer, and
(d) etching the exposed first layer using the second layer, the silicon containing layer, and the metal containing layer as a mask.

### [E2]

The etching method according to [E1], in which
in (c), the metal containing layer is formed without generating a plasma.

### [E3]

The etching method according to [E2], in which
in (c), the metal containing layer is formed by a chemical vapor deposition method or an atomic layer deposition method.

### [E4]

The etching method according to any one of [E1] to [E3], in which
in (c), a temperature of the substrate is 60° C. or higher.

### [E5]

The etching method according to any one of [E1] to [E4], further including:
a second layer formation step of forming the second layer on the underlayer layer before (a), in which
in the second layer formation step, a scum on the substrate is removed after the second layer is formed.

### [E6]

The etching method according to any one of [E1] to [E5], in which
in (b), the silicon containing layer is formed without generating a plasma.

### [E7]

The etching method according to any one of [E1] to [E5] further including:
exposing the silicon containing layer to a plasma generated from a hydrogen containing gas after (b) and before (c).

### [E8]

The etching method according to any one of [E1] to [E7] further including:
removing a part of the silicon containing layer after (b) and before (c).

### [E9]

The etching method according to any one of [E1] to [E8] further including:
exposing the metal containing layer to a plasma generated from a hydrogen containing gas after (c) and before (d).

### [E10]

The etching method according to any one of [E1] to [E9] further including:
removing a part of the metal containing layer after (c) and before (d).

### [E11]

The etching method according to any one of [E1] to [E10] further including:
forming a deposition layer on a surface of the metal containing layer after (c) and before (d).

### [E12]

The etching method according to any one of [E1] to [E11], in which
the silicon containing layer has a first portion located on a top surface of the second layer and a second portion located on a side surface of the second layer, and
a thickness of the first portion is larger than a thickness of the second portion.

### [E13]

The etching method according to any one of [E1] to [E12], in which
the metal containing layer contains at least one of W, WSi_{X}, Mo, and MoSi_{X}F_{Y}, and
each of X and Y is a positive number.

### [E14]

A plasma processing apparatus including:
a chamber,
a substrate support provided in the chamber and including a temperature control module,
a gas supply configured to supply a processing gas into the chamber,
a plasma generator configured to generate a plasma from the processing gas in the chamber, and
a controller configured to control the temperature control module, the gas supply, and the plasma generator such that, in a state in which a substrate including a first layer and a second layer having a pattern on the first layer is supported by the substrate support, a silicon containing layer is formed on a surface of the second layer in preference to a surface of the first layer, a metal containing layer is formed on a surface of the silicon containing layer, and the exposed first layer is etched using the second layer, the silicon containing layer, and the metal containing layer as a mask.

From the foregoing, it will be appreciated that various embodiments of the present disclosure have been described herein for purposes of illustration, and that various modifications may be made without departing from the scope and spirit of the present disclosure. Therefore, the various embodiments disclosed herein are not intended to be limiting, with the true scope and spirit being indicated by the following claims.

### REFERENCE SIGNS LIST

1: plasma processing apparatus
2: controller
10: plasma processing chamber
11: substrate support
12: plasma generator
20: gas supply
DL: deposition layer
ML: metal containing layer
P1: first portion
P2: second portion
RL: resist layer
SF: side surface
SL: silicon containing layer
TF: top surface
UML: underlayer

1. An etching method comprising:
(a) providing a substrate that includes a first layer and a second layer, the second layer having a pattern on the first layer,
(b) forming a silicon containing layer on a surface of the second layer,
(c) forming a metal containing layer on a surface of the silicon containing layer, and
(d) etching the exposed first layer using the second layer, the silicon containing layer, and the metal containing layer as a mask.

2. The etching method according to claim 1, wherein
in (c), the metal containing layer is formed without generating a plasma.

3. The etching method according to claim 2, wherein
in (c), the metal containing layer is formed by a chemical vapor deposition method or an atomic layer deposition method.

4. The etching method according to claim 3, wherein
in (c), a temperature of the substrate is 60° C. or higher.

5. The etching method according to claim 1, further comprising:
a second layer formation step of forming the second layer on the first layer before (a), wherein
in the second layer formation step, a scum on the substrate is removed after the second layer is formed.

6. The etching method according to claim 1, wherein
in (b), the silicon containing layer is formed without generating a plasma.

7. The etching method according to claim 1, further comprising:
exposing the silicon containing layer to a plasma generated from a hydrogen containing gas after (b) and before (c).

8. The etching method according to claim 1, further comprising:
removing a part of the silicon containing layer after (b) and before (c).

9. The etching method according to claim 1, further comprising:
exposing the metal containing layer to a plasma generated from a hydrogen containing gas after (c) and before (d).

10. The etching method according to claim 1, further comprising:
removing a part of the metal containing layer after (c) and before (d).

11. The etching method according to claim 1, further comprising:
forming a deposition layer on a surface of the metal containing layer after (c) and before (d).

12. The etching method according to claim 1, wherein
the silicon containing layer has a first portion located on a top surface of the second layer and a second portion located on a side surface of the second layer, and
a thickness of the first portion is larger than a thickness of the second portion.

13. The etching method according to claim 1, wherein
the metal containing layer contains at least one of the following: W, WSi_{X}, Mo, and MoSi_{X}F_{Y}, and
each of X and Y is a positive number.

14. A plasma processing apparatus comprising:
a chamber,
a substrate support provided in the chamber and including a temperature control module,
a gas supply configured to supply a processing gas into the chamber,
a plasma generator configured to generate a plasma from the processing gas in the chamber, and
processing circuitry configured to control the temperature control module, the gas supply, and the plasma generator such that, in a state in which a substrate including a first layer and a second layer is supported by the substrate support, a silicon containing layer is formed on a surface of the second layer, a metal containing layer is formed on a surface of the silicon containing layer, and the exposed first layer is etched using the second layer, the silicon containing layer, and the metal containing layer as a mask, the second layer has a pattern on the first layer.

15. The plasma processing apparatus according to claim 14, wherein
the metal containing layer is formed without generating a plasma.

16. The plasma processing apparatus according to claim 15, wherein
the metal containing layer is formed by a chemical vapor deposition method or an atomic layer deposition method.

17. The plasma processing apparatus according to claim 16, wherein
the metal containing layer is formed while a temperature of the substrate is 60° C. or higher.

18. The plasma processing apparatus according to claim 14, wherein the processing circuitry is further configured to:
form a deposition layer on a surface of the metal containing layer after forming the metal containing layer and before the etching.

19. The plasma processing apparatus according to claim 14, wherein
the silicon containing layer has a first portion located on a top surface of the second layer and a second portion located on a side surface of the second layer, and
a thickness of the first portion is larger than a thickness of the second portion.

20. The plasma processing apparatus according to claim 14, wherein
the metal containing layer contains at least one of the following: W, WSi_{X}, Mo, and MoSi_{X}F_{Y}, and
each of X and Y is a positive number.
